(19) United States
(12) Patent Application Publication
(10) Pub. No.: US 2011/0101341 A1
(43) Pub. Date: May 5, 2011

(54) SUB-ASSEMBLY FOR USE IN FABRICATING PHOTO-ELECTROCHEMICAL DEVICES AND A METHOD OF PRODUCING A SUB-ASSEMBLY

(75) Inventors: Olivier Bellon, New South Wales (AU); Sylvia Medlyn Tulloch, New South Wales (AU)

(73) Assignee: DYESOL LTD., Queanbeyan, NSW (AU)

(21) Appl. No.: 12/919,616

(22) PCT Filed: Feb. 25, 2009
(86) PCT No.: PCT/AU2009/000205

§ 371 Date: Dec. 23, 2010

(30) Foreign Application Priority Data
Feb. 26, 2008 (AU) 208900906

(51) Int. Cl. H01L 29/22; H01L 21/283

(52) U.S. Cl. 257/43; 438/104; 257/E29.094; 257/E21.159

(57) ABSTRACT

A sub assembly is disclosed for use in fabrication of photo-electrochemical devices including: a first layer which includes a semiconductor material; a second layer which is electrically conductive; and wherein the second layer supports the first layer. Methods of producing the sub assembly are also disclosed.

### TECHNICAL FIELD

This invention relates to a sub-assembly for use in fabricating photo-electrochemical devices and a method of producing a sub-assembly. In one form, the assembly includes a meso-porous TiO₂ film and is for use in fabricating a solar cell.

### SUMMARY OF THE INVENTION

In a first aspect the present invention provides a sub assembly for use in fabrication of photo-electrochemical devices including: a first layer which includes a semiconductor material; a second layer which is electrically conductive; and wherein the second layer supports the first layer.

The second layer may be in the form of a metallic mesh.

The second layer may be in the form of a perforated foil.

The first layer may include oxide particles.

The first layer may include any of TiO2, Fe2O3, ZnO, Sn2O3 and WO3.

The sub assembly may further include an interlayer disposed between the first and second layers.

The interlayer may include any of TiO2, ZrO2 or other oxide material, diamond, semimetallic, metallic (and multimetal) nitrides, oxides, borides, phosphides, silicides such as silicides of niobium, molybdenum, tantalum, tungsten or vanadium and combinations thereof, oxynitrides, titanium nitride (TiN), zirconium nitride, boron carbide and inert metals such as Ti, W and precious metals such as Pt, Rh, Pd.

In a second aspect the present invention provides a method of producing a sub assembly for use in fabrication of photo-electrochemical devices including the steps of: joining a first layer with a second layer on a carrier sheet; the first layer includes oxide particles; the second layer is electrically conductive; and removing the carrier sheet.

The first layer may be applied to the carrier sheet and then the second layer may be subsequently applied to the first layer.

The second layer may be applied to the carrier sheet and the first layer imay be subsequently applied to the second layer.

The first layer may be applied by way of applying a solution.

The solution may include a dispersant.

The solution may include a binder

The solution may include any of a plasticiser, a defoamer, a thickener or a wetting agent.

The thickness of the first layer may lie in the range of 5 to 100 um.

The thickness of the first layer may lie in the range of 10 to 100 um.

The thickness of the first layer may lie in the range of 5 to 20 um.

The layers may be joined by way of an interlayer.

The interlayer may include any of TiO2, ZrO2 or other oxide material, diamond, semimetallic, metallic (and multimetal) nitrides, oxides, borides, phosphides, silicides such as silicides of niobium, molybdenum, tantalum, tungsten or vanadium and combinations thereof, oxynitrides, titanium nitride (TiN), zirconium nitride, boron carbide, inert metal such as Ti, W and precious metals such as Pt, Rh, Pd.

The method may further include the step of firing the sub assembly.

The first layer may include any one of TiO2, Fe2O3, ZnO, Sn2O3 and WO3.

The method may further include the step of applying a release agent to the carrier sheet.

### BRIEF DESCRIPTION OF THE DRAWINGS

An embodiment of the present invention will now be described, by way of example only, with reference to the accompanying drawings, in which:

FIG. 1 is a schematic side view of a first step for forming a sub assembly according to an embodiment of the invention;

FIG. 2 illustrates a second step and shows a metallic mesh later applied to the arrangement of FIG. 1;

FIG. 3 shows the arrangement of FIG. 2 with carrier film removed;

FIG. 4 is a top view of the sub-assembly of FIG. 3;

FIGS. 5 and 6 illustrate a variation to the method illustrated in FIGS. 1 to 3;

FIG. 7 is a top view of the sub assembly of FIG. 6;

FIGS. 8 to 11 illustrate steps in an alternative embodiment of the method of the invention; and

FIG. 12 illustrates a solar cell fabricated using the sub assembly of FIG. 3.

### DETAILED DESCRIPTION OF THE PREFERRED EMBODIMENT

The invention involves thin titanium dioxide films which are applied to a metal mesh or grid and then fired. The result is a layer of pre-sintered titanium dioxide carried on a metal mesh or grid. The presence of the mesh or grid eliminates the need for TCO or any conductive coating to be applied adjacent the film in subsequent processing steps for manufacturing photo-electrochemical devices such as solar cells. Thus, a simple transparent sealing layer can be used. Further, the sub-assembly can form the working electrode of a solar cell, and the light hitting the cell need not penetrate a layer of electrolyte prior to hitting the working electrode thus improving cell efficiency. The mesh also allows the film to be handled easily (eg. for transfer onto other substrates). Such films can be applied to plastic substrates such as PET or PEN films at relatively low temperatures.

One advantage of the present invention is the separation of the film preparation and film firing steps from the film application process. Thus the methods of the present invention allow for larger flexibility and ease in device manufacturing processes, easy handling of the material for transfer onto other supports such as polymer films at relatively low temperatures, processing of large surface areas at a time and convenient transport of prefabricated films.

Two processes for forming sub-assemblies according to the invention will now be described:

### Embodiment 1

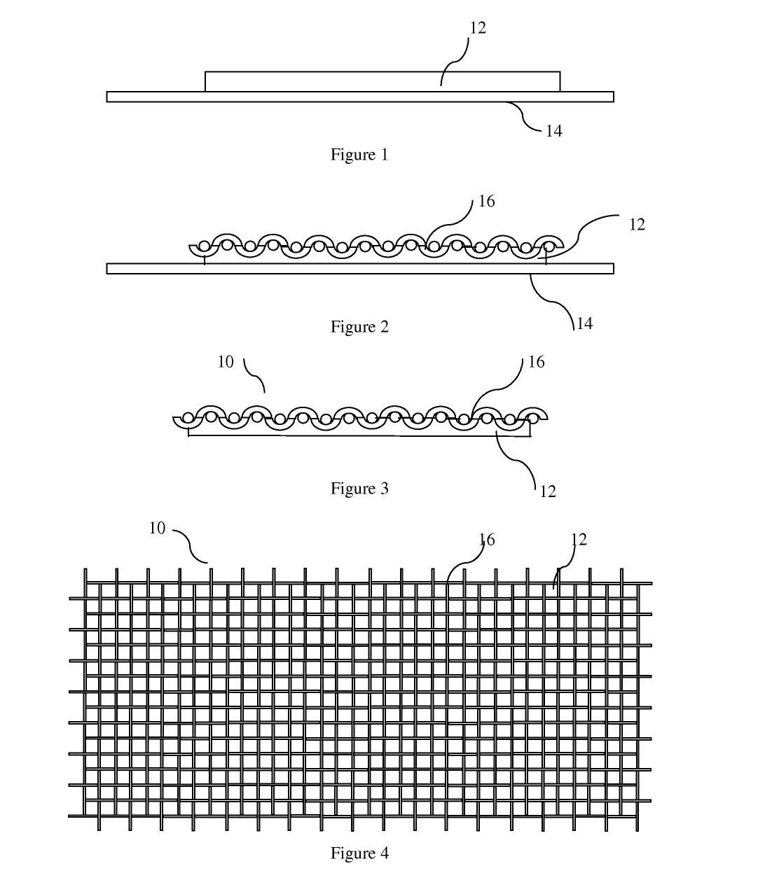

Referring to FIG. 1, a green (unfired) TiO2 film 12 is prepared by a coating process such as the doctor blade process (tape casting) on a carrier film or foil 14 (cellulose acetate, Mylar, etc). The TiO2 solution contains TiO2 powder, dispersant, binders and plasticiser enabling the film to be cast down to a very low thickness (10 to 100 um) and to release from the carrier after drying. Typical film thickness is ˜10-20 um. Referring to FIG. 2, a metal mesh 16 or grid based on metal such as steel, stainless steel, Ti, Mo, W, surface modified such metal, coated such metal or other conductive material such as TiN of appropriate thickness (depending on the application) is laid onto the film 12 and a small pressure is applied to partially embed the mesh into the film. The mesh is formed from wire strands of a thickness of between 10 to 50 um.

Optionally the mesh 12 may be modified by a thin interlayer to provide improved adhesion and/or electrical contact characteristics. The interlayer may be formed from TiO2, ZrO2 or other oxide material, diamond, semimetallic, metallic (and multimetal) nitrides, oxides, borides, phosphides, silicides such as silicides of niobium, molybdenum, tantalum, tungsten or vanadium and combinations thereof, oxynitrides, titanium nitride (TiN), zirconium nitride, boron carbide and metals inert to other component of the photo-electrochemical device for which it is intended to be used such as Ti, W, Mo and precious metals such as Pt, Rh, Pd.

The interlayer may serve to protect the film layer from electrolyte when fabricated into a solar cell. The interlayer may be made a dense film.

Referring to FIGS. 3 and 4, after drying of the oxide layer, the plastic carrier 14 is removed and the mesh 16 and film 12 are fired (mesh down) as required (at any temperature the metal mesh can withstand) to remove the organics from the film 12. As relatively high porosity is required, very little shrinkage occurs, eliminating the risk of the film cracking in the unsupported areas of the mesh with appropriate firing conditions. The result is sub-assembly 10 which can be used at a later time in fabrication of photo-electrochemical devices such as solar cells, photo-electrochemical decomposition of impurities, photochemical water treatment, electro-chromic devices and sensors.

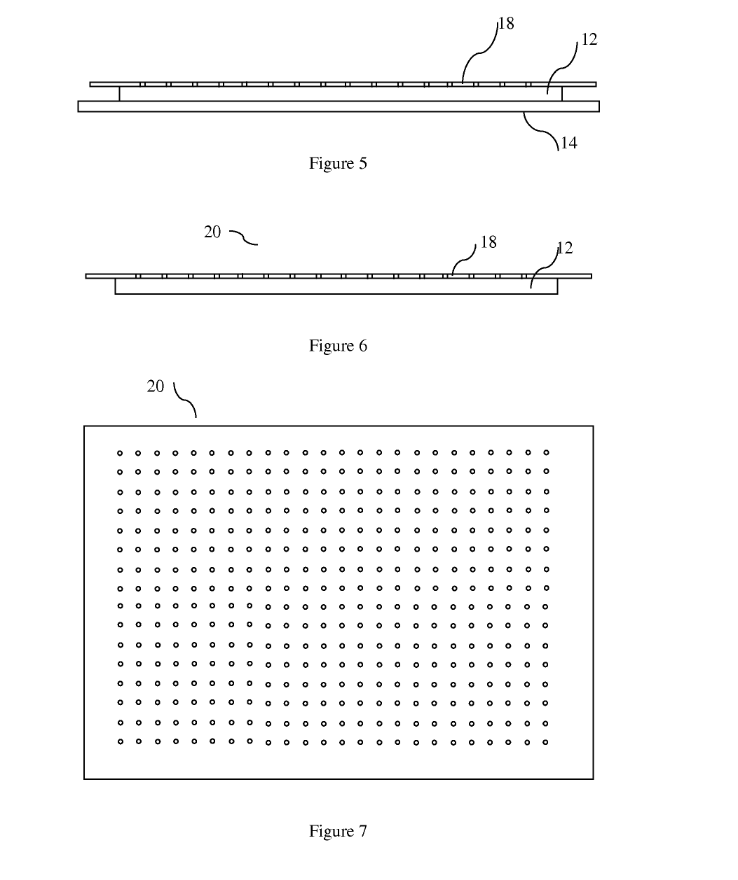

Referring to FIGS. 5, 6 & 7, in a variation of this embodiment, perforated foil 18 is used in place of mesh 12. The fabrication steps are the same as those described in relation to FIGS. 1 to 4. The resulting sub-assembly is indicated by reference numeral 20.

### Embodiment 2

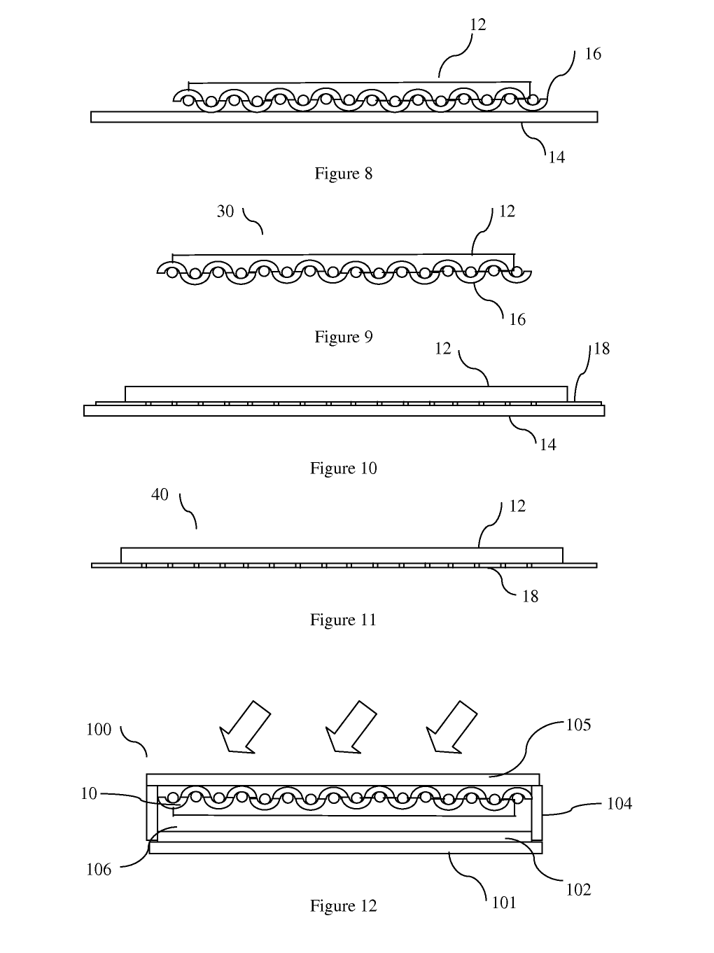

Referring to FIGS. 8 and 9, a metal mesh 16 or grid base of on metal such as steel, stainless steel, Ti, Mo, W, surface modified such metal, coated such metal or other conductive material such as TiN of appropriate thickness is laid onto a plastic carrier 14, ensuring perfect flatness is achieved. A TiO2 solution containing the TiO2 powder, dispersant, binders and plasticiser is then deposited by a coating process such as the doctor blade process (tape casting) onto the mesh. The solution is cast in such a way that the final dry film 12 thickness is either the same thickness as the mesh, or slightly thicker, as required for the particular application.

The plastic carrier 14 is then removed and the mesh 16 and film 12 are fired to yield a sub assembly indicated by reference numeral 30.

Referring to FIGS. 10 and 11, in a variation of this embodiment, perforated foil 18 is used in place of mesh 12. The fabrication steps are the same as those described in relation to FIGS. 8 and 9. The potential materials for the perforated foil are the same as for the mesh. The resulting sub-assembly is indicated by reference numeral 40.

After firing, the solid structure of the mesh 12 or foil 18 allows for easy handling. Specific sizes can be cut (laser cutting is advised to reduce vibration stresses in the process) and applied to polymer substrate films such as PET or PEN. Optionally some heat treatment may be applied to optimise the contact between the two materials.

Sub-assemblies according to embodiments of the invention can be handled and transported easily to be used for dye-sensitised solar cells in a high-speed reel-to-reel process. They can then be applied at ambient or relatively low temperatures which are compatible with polymer substrates.

In variations of the above-described embodiments, a release agent may be used to assist in removal of the carrier sheet.

In variations of the above-described embodiments, the mesh may be formed from any conductive material that could withstand the heat treatment step, such as Mo, W or TiN.

In variations on the above described embodiments, the film may be affixed to the conductive layer by heat treatment, mechanical pressure, UV curing, or use of adhesive agents.

In variations on the above described embodiments, the solution used to form the film layer may further include defoamers, thickeners or wetting agents.

Referring to FIG. 12, a solar cell 100 is shown having been constructed using sub assembly 10. The cell 100 is constructed in the following manner. Firstly, the sub-assembly is embedded into substrate 105 which is formed from a transparent polymer such as PET or PEN. A lower glass substrate 101 is provided with a conductive layer 102. The conductive layer may be formed from conductive transparent oxides such as ITO, FTO and any metal that does not chemically react with other components of the cell. The oxide layer of assembly 10 is sensitised by a suitable dye, and covered by upper substrate 105 with sub-assembly 10 attached. The cell is sealed with side walls 104 and an electrolyte 106 is introduced into the cell. It can be seen that sunlight indicated by arrows strikes the sub-assembly 10 which forms the working electrode of the cell.

Any reference to prior art contained herein is not to be taken as an admission that the information is common general knowledge, unless otherwise indicated.

Finally, it is to be appreciated that various alterations or additions may be made to the parts previously described without departing from the spirit or ambit of the present invention.

1-22. (canceled)

23. A sub assembly for use in fabrication of photo-electrochemical devices comprising:
a first layer which includes a semiconductor material;
a second layer which is electrically conductive; and
wherein the second layer supports the first layer.

24. The sub assembly according to claim 23, wherein the second layer is in the form of a metallic mesh.

25. The sub assembly according to claim 23, wherein the second layer is in the form of a perforated foil.

26. The sub-assembly according to claim 23, wherein the first layer includes oxide particles.

27. The sub-assembly according to claim 26, wherein the first layer includes any of TiO₂, Fe₂O₃, ZnO, Sn₂O₃ and WO₃.

28. The sub assembly according to claim 23, further including an interlayer disposed between the first and the second layers.

29. The sub assembly according to claim 28, wherein the interlayer includes any of TiO2, ZrO2 or other oxide material, diamond, semimetallic, metallic (and multimetal) nitrides, oxides, borides, phosphides, silicides such as silicides of niobium, molybdenum, tantalum, tungsten or vanadium and combinations thereof, oxynitrides, titanium nitride (TiN), zirconium nitride, boron carbide and inert metals such as Ti, W and precious metals such as Pt, Rh, Pd.

30. A method of producing a sub assembly for use in fabrication of photo-electrochemical devices, the method comprising the steps of:
joining a first layer with a second layer on a carrier sheet;
the first layer includes oxide particles;
the second layer is electrically conductive; and
removing the carrier sheet.

31. The method according to claim 30, further comprising the step of applying the first layer to the carrier sheet and then subsequently applying the second layer to the first layer.

32. The method according to claim 30, further comprising the step of applying the second layer to the carrier sheet and then subsequently applying the first layer to the second layer.

33. The method according to claim 30, further comprising the step of applying the first layer by way of applying a solution.

34. The method according to claim 33, further comprising the step of adding a dispersant to the solution.

35. The method according to claim 33, further comprising the step of including a binder to the solution.

36. The method according to claim 33, further comprising the step of including any of a plasticiser, a defoamer, a thickener or a wetting agent in the solution.

37. The method according to claim 30, further comprising the step of forming a thickness of the first layer to lie within a range of 5 to 100 μm.

38. The method according to claim 30, further comprising the step of forming a thickness of the first layer to lie within a range of 10 to 100 μm.

39. The method according to claim 30, further comprising the step of forming a thickness of the first layer to lie within a range of 5 to 20 μm.

40. The method according to claim 30, further comprising the step of joining the layers by way of an interlayer.

41. The method according to claim 40, further comprising the step of the interlayer including any of TiO2, ZrO2 or other oxide material, diamond, semimetallic, metallic (and multimetal) nitrides, oxides, borides, phosphides, silicides such as silicides of niobium, molybdenum, tantalum, tungsten or vanadium and combinations thereof, oxynitrides, titanium nitride (TiN), zirconium nitride, boron carbide, inert metal such as Ti, W and precious metals such as Pt, Rh, Pd.

42. The method according to claim 30, further comprising the step of firing the sub assembly.

43. The method according to claim 30, further comprising the step of the first layer including any one of TiO₂, Fe₂O₃, ZnO, Sn₂O₃ and WO₃.

44. The method according to claim 30, further comprising the step of applying a release agent to the carrier sheet.
